(19) United States
(12) Patent Application Publication
(10) Pub. No.: US 2021/0135050 A1
(43) Pub. Date: May 6, 2021

(54) TEMPLATE SUBSTRATE, ELECTRONIC DEVICE, LIGHT EMITTING DEVICE, METHOD OF MANUFACTURING TEMPLATE SUBSTRATE, AND METHOD OF MANUFACTURING ELECTRONIC DEVICE

(71) Applicant: Sony Corporation, Tokyo (JP)

(72) Inventors: Kunihiko TASAI, Tokyo (JP); Hiroshi NAKAJIMA, Kanagawa (JP); Hidekazu KAWANISHI, Tokyo (JP); Katsunori YANASHIMA, Kanagawa (JP)

(21) Appl. No.: 16/638,662

(22) PCT Filed: Jun. 19, 2018
(86) PCT No.: PCT/JP2018/023254

§ 371 Date: Feb. 12, 2020

(30) Foreign Application Priority Data
Aug. 14, 2017 (JP) 2017-156416

(51) Int. Cl. H01L 33/12; H01L 21/02; H01L 33/00

(52) U.S. Cl. CPC H01L 33/12; H01L 21/02381; H01L 21/0242; H01L 21/02458; H01L 33/32; H01L 21/0254; H01L 21/02598; H01L 33/007; H01L 21/02502

(57) ABSTRACT

A template substrate including: a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed; a second layer that is stacked on the first layer to be lattice-matched to the first layer and includes Al_{y}Ga_{(1-y)}N (0≤y<1); and a third layer that is provided opposed to the first layer with the second layer being interposed therebetween, the third layer being lattice-matched to the second layer and including Al_{z2}In_{z1}Ga_{(0-z1-z2)}N (0<z1<1, 0≤z2<1).

### TECHNICAL FIELD

The present technology relates to a template substrate using, for example, a gallium nitride (GaN)-based material and a method of manufacturing the same, an electronic device including this template substrate and a method of manufacturing the same, and a light emitting device.

### BACKGROUND ART

Development of light emitting devices using gallium nitride (GaN)-based materials has been actively performed. Examples of the light emitting device include a semiconductor laser (LD: Laser Diode), a light emitting diode (LED: Light Emitting Diode), and the like. In the light emitting device as described above, for example, a light emitting layer is provided on a template substrate (see, for example, PTL 1).

### CITATION LIST

### Patent Literature

PTL 1: Japanese Unexamined Patent Application Publication (Published Japanese Translation of PCT Application) No. 2010-514192

### SUMMARY OF THE INVENTION

Planarity of a front surface, a large number of defects, single crystalline nature, and the like in a semiconductor layer included in this template substrate affect the planarity, defect density, the single crystalline nature, and the like in the light emitting layer. It is desirable to enhance crystalline quality of the semiconductor layer included in the template substrate as described above.

Hence, it is desirable to provide a template substrate that makes it possible to enhance crystalline quality and a method of manufacturing the same, an electronic device that includes this template substrate and a method of manufacturing the same, and a light emitting device.

A template substrate according to an embodiment of the present technology includes: a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed; a second layer that is stacked on the first layer to be lattice-matched to the first layer and includes Al_{y}Ga_{(1-y)}N (0≤y<1); and a third layer that is provided opposed to the first layer with the second layer being interposed therebetween, the third layer being lattice-matched to the second layer and including Al_{z2}In_{z1}Ga_{(1-z1-z2)}N (0<z1<1, 0≤z2<1).

An electronic device according to an embodiment of the present technology includes a functional layer on the template substrate according to the embodiment of the present technology described above.

A light emitting device according to an embodiment of the present technology includes a light emitting layer on the template substrate according to the embodiment of the present technology described above.

In the template substrate, the electronic device and the light emitting device according to the embodiments of the present technology, the third layer is stacked on the lattice-relaxed first layer with the second layer that does not contain indium (In) being interposed therebetween, and thus as compared with the first layer, the quality of the crystal of the third layer is improved.

A method of manufacturing a template substrate according to an embodiment of the present technology includes: forming a first layer that includes Alₓ₂Inₓ₁Ga₍₁₋ₓ₁₋ₓ₂₎N (0<x1<1, 0≤x2<1) and has a lattice constant al in an in-plane direction greater than a lattice constant of GaN in the in-plane direction, the first layer being lattice-relaxed; forming, on the first layer, a second layer in which Al_{y}Ga_{(1-y)}N (0≤y<1) is coherently grown; and forming, on the second layer, a third layer in which Al_{z2}In_{z1}Ga_{(1-z1-z2)}N (0<z1<1, 0≤z2<1) is coherently grown.

A method of manufacturing an electronic device according to an embodiment of the present technology includes forming, after formation of a template substrate using the method of manufacturing the template substrate according to the embodiment of the present technology described above, a functional layer on the template substrate.

In the method of manufacturing the template substrate and the method of manufacturing the electronic device according to the embodiments of the present technology, on the lattice-relaxed first layer, the second layer that does not contain indium (In) is formed, and the third layer is formed on the second layer. Hence, the third layer is formed in which the quality of the crystal is improved as compared with the first layer.

In the template substrate, the electronic device, and the light emitting device according to the embodiments of the present technology, the second layer that does not contain indium (In) is provided between the first layer and the third layer, and according to the method of manufacturing the template substrate and the method of manufacturing the electronic device of the embodiments of the present technology, the second layer that does not contain indium (In) is formed on the first layer, and the third layer is formed on the second layer. In this way, it is possible to enhance the quality of the crystal of the third layer. The third layer is disposed in a position that is closer to the light emitting layer and the like than to the first layer.

It is to be noted that the contents described above are mere examples of the present disclosure. The effects of the present discloser are not necessarily limited to the effects described above, and may be other different effects or may further include other effects.

### BRIEF DESCRIPTION OF THE DRAWINGS

FIG. 1 is a schematic cross-sectional view of a schematic configuration of a light emitting device according to a first embodiment of the present technology.

FIG. 2 is a schematic cross-sectional view of another example of a configuration of a first layer illustrated in FIG. 1.

FIG. 3 illustrates lattice constants of the first layer, a second layer, and a third layer illustrated in FIG. 1.

FIG. 4 illustrates a relationship between degree of inconsistency of the lattice constants of the first layer and the third layer illustrated in FIG. 1 and single crystalline nature of the third layer.

FIG. 5 illustrates a relationship between indium (In) composition of the first layer illustrated in FIG. 1 and critical values of the thickness of the second layer.

FIG. 6 is a schematic cross-sectional view of another example of a configuration of the second layer illustrated in FIG. 1.

FIG. 7 is a schematic cross-sectional view of another example of a configuration of the third layer illustrated in FIG. 1.

FIG. 8A is a schematic cross-sectional view of a step of manufacturing the light emitting device illustrated in FIG. 1.

FIG. 8B is a schematic cross-sectional view of a step following FIG. 8A.

FIG. 8C is a schematic cross-sectional view of a step following FIG. 8B.

FIG. 9 is a schematic cross-sectional view of a configuration of a template substrate according to Comparative Example 1.

FIG. 10 is a schematic cross-sectional view of a configuration of a template substrate according to Comparative Example 2.

FIG. 11 illustrates a cross-sectional profile of the third layer illustrated in FIG. 1.

FIG. 12 is a schematic cross-sectional view of a configuration of a modification example of the light emitting device illustrated in FIG. 1.

FIG. 13 is a schematic cross-sectional view of a schematic configuration of a light emitting device according to a second embodiment of the present technology.

FIG. 14 is a schematic plan view of another example of the light emitting device illustrated in FIG. 13.

FIG. 15 is a schematic cross-sectional view of another example of the light emitting device illustrated in FIG. 1, etc.

### MODES FOR CARRYING OUT THE INVENTION

Embodiments of the present technology are described in detail below with reference to drawings. It is to be noted that description is given in the following order.
1. First Embodiment
   A light emitting device in which a second layer that does not contain indium (In) is provided between a first layer and a third layer
2. Modification example
   An example of using a substrate including a material other than gallium nitride (GaN)-based materials
3 Second embodiment
   A template substrate in which a first layer has a thickness greater than a critical film thickness

### First Embodiment

FIG. 1 illustrates a schematic cross-sectional configuration of a light emitting device (a light emitting device 1) according to a first embodiment of the present technology. The light emitting device 1 is, for example, a semiconductor laser, a light emitting diode, or the like that emits light of wavelengths in a visible region, and includes a light emitting layer 20 on a template substrate 10. The template substrate 10 includes a substrate 11, a buffer layer 12, a first layer 13, a second layer 14, and a third layer 15 in this order, and the light emitting layer 20 is provided on the third layer 15.

The substrate 11 is, for example, a gallium nitride (GaN) substrate, and the thickness thereof is, for example, 300 μm to 500 μm. For example, a c-plane of the gallium nitride (GaN) substrate is used as a main plane.

The buffer layer 12 provided between the substrate 11 and the first layer 13 is used to lattice-relax the first layer 13. The buffer layer 12 is a so-called low-temperature buffer layer, and is, for example, a non-single crystal layer that is formed at a low temperature of about 400° C. to 750° C. Examples of the non-single crystal include an amorphous form, a polycrystal, and the like. The buffer layer 12 includes, for example, gallium nitride (GaN), gallium indium nitride (GaInN), gallium aluminum nitride (AlGaN), aluminum nitride (AlN), or aluminum gallium indium nitride (AlGaInN). The thickness of the buffer layer 12 is, for example, 10 nm to 100 nm.

The first layer 13 on the buffer layer 12 is provided in contact with the buffer layer 12. The first layer 13 includes Alₓ₂Inₓ₁Ga₍₁₋ₓ₁₋ₓ₂₎N (0<x1<1, 0≤x2<1). An indium (In) composition c1 (%) of the first layer 13 is, for example, 1% to 30%. The first layer 13 provided on the buffer layer 12 has a lattice constant a1 in an in-plane direction greater than a lattice constant of gallium nitride (GaN) in the in-plane direction (e.g., c-plane), and is lattice-relaxed. For example, the first layer 13 is fully relaxed. The thickness of the first layer 13 is, for example, 100 nm to 2000 nm. The thickness of the first layer 13 is set equal to or greater than 100 nm and is more preferably set equal to or greater than 500 nm, thus allowing for formation of a crystal that has an excellent single crystalline nature and a low dislocation density, as compared with a case where the thickness is less than 100 nm.

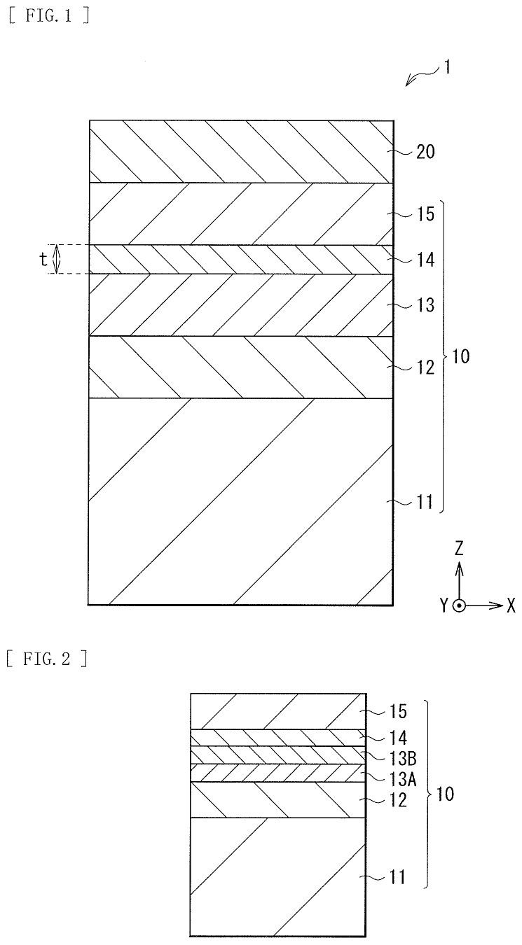

FIG. 2 illustrates an example of the configuration of the template substrate 10 that includes a plurality of first layers 13A and 13B between the buffer layer 12 and the second layer 14. As described above, the template substrate 10 may include the plurality of first layers 13A and 13B. The first layers 13A and 13B differ from each other in, for example, the indium (In) composition c1 (%). Although in FIG. 2, the first layers 13A and 13B in which two layers are stacked are illustrated, the first layer 13 may include three or more layers that are stacked. The first layer 13 that has a superlattice structure may be provided. In the first layer 13, the indium (In) composition c1 (%) may be continuously changed in the direction of thickness. Along a direction extending from the buffer layer 12 toward the second layer 14, the indium composition c1 (%) of the first layer 13 may be gradually increased or may be gradually decreased.

The second layer 14 provided on the first layer 13 includes Al_{y}Ga_{(1-y)}N (0≤y<1), and does not contain indium (In). The third layer 15 opposed to the first layer 13 with the second layer 14 layer being interposed therebetween includes Al_{z2}In_{z1}Ga_{(1-z1-z2)}N (0<z1<1, 0≤z2<1), and contains indium. In the present embodiment, the third layer 15 is stacked on the lattice-relaxed first layer 13 with the second layer 14 being interposed therebetween. In this way, it is possible to enhance the quality of the crystal of the third layer 15 as compared with the first layer 13, although details are described later. For example, the third layer 15 is lower in the half-value width of the peak of ω scan in X-ray diffraction than the first layer 13, and thus the third layer 15 has a higher single crystalline nature than the first layer 13. The third layer 15 is lower in threading dislocation density than the first layer 13, and thus the third layer 15 has a lower defect density than the first layer 13. The third layer 15 has smaller irregularities in the front surface than the first layer 13 so as to have a high degree of planarity.

The second layer 14 is coherently grown on the first layer 13, and the third layer 15 is coherently grown on the second layer 14. In other words, the second layer 14 is stacked on the first layer 13 to be lattice-matched thereto, and the third layer 15 is stacked on the second layer 14 to be lattice-matched thereto. A lattice constant a2 of the second layer 14 in the in-plane direction is substantially equal to the lattice constant a1 of the first layer 13 in the in-plane direction, and a lattice constant a3 of the third layer 15 in the in-plane direction is substantially equal to the lattice constant a2 of the second layer 14 in the in-plane direction.

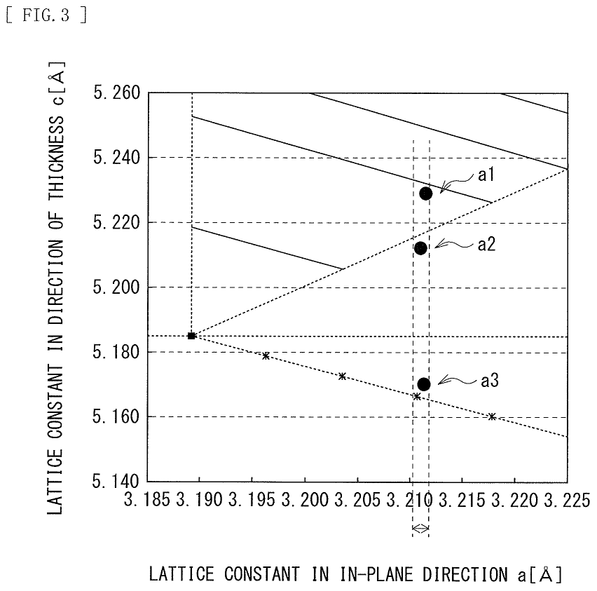

FIG. 3 illustrates examples of the respective lattice constants a1, a2 and a3 of the first layer 13, the second layer 14 and the third layer 15 in the in-plane direction. As described above, the lattice constants a1, a2, and a3 are substantially equal to one another, and for example, the degrees of inconsistency thereof (a1 and a2, a2 and a3, and a1 and a3) are less than 0.005%. In particular, an inconsistency degree d (%) of the lattice constant a3 of the third layer 15 in the in-plane direction with respect to the lattice constant a1 of the first layer 13 in the in-plane direction is less than 0.083%, and is preferably less than 0.063%. The inconsistency degree d (%) is represented by formula (1) below.

d(%)=|(a3−a1)|/a1×100 (1)

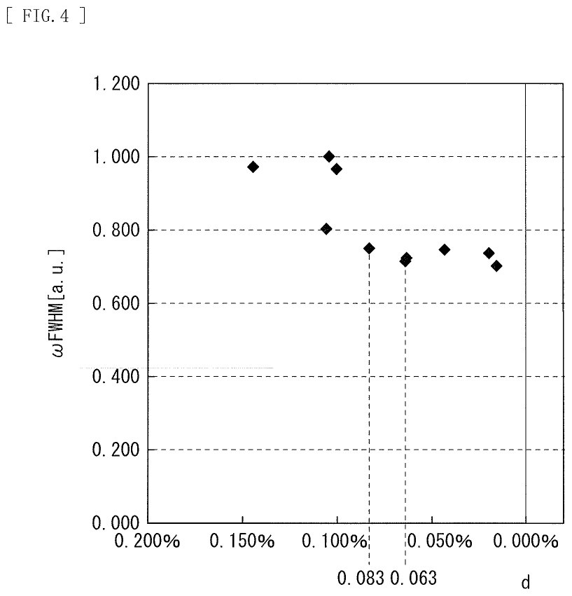

FIG. 4 illustrates a relationship between the inconsistency degree d (%) represented by formula (1) and a half-value width ωFWHM (a.u.) of the peak of ω scan in the X-ray diffraction of the third layer 15. As described above, as the inconsistency degree d is increased, the half-value width is increased. In other words, it is suggested that when lattice relaxation occurs when the second layer 14 and the third layer 15 are stacked, the second layer 14 between the first layer 13 and the third layer 15 does not function effectively, and that thus the single crystalline nature of the third layer 15 is lowered. When the inconsistency degree d (%) is less than 0.083%, and is preferably less than 0.063%, for example, the half-value width ωFWHM (a.u.) of the third layer 15 is less than 0.8 (a.u.), and thus it is possible to obtain a sufficiently high single crystalline nature.

For example, the thickness t of the second layer 14 is adjusted, and thus it is possible to decrease the inconsistency degree d, and the indium (In) composition c1 (%) of the first layer 13 and the thickness t (nm) of the second layer 14 including GaN (y=0 described above) preferably satisfy formula (2) below. The thickness t of the second layer 14 indicates, for example, a size in the z-direction of FIG. 1.

t(nm)<1018.9×e^{-50.71×c1} (2)
where 2.0%<c1<6.0% holds true in formula (2).

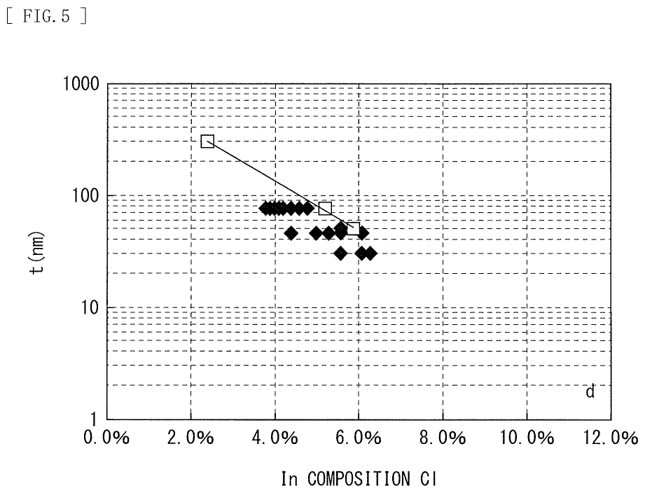

FIG. 5 illustrates a relationship between the indium (In) composition c1 (%) of the first layer 13 and the thickness t (nm) of the second layer 14 when the inconsistency degree d (%) represented by formula (1) is less than 0.063%. Formula (2) described above is derived by a straight line connecting the critical points of c1 and t at the time when the inconsistency degree d (%) is less than 0.063%. Formula (2) is applied within a range of 2.0%<c1<6.0%. When c1 is equal to or greater than 6.0%, the straight line connecting the critical points in FIG. 5 is more gentle. Hence, when the indium (In) composition c1 (%) of the first layer 13 is equal to or greater than 6.0%, it is sufficient for the thickness t of the second layer 14 to be equal to or less than 49 nm.

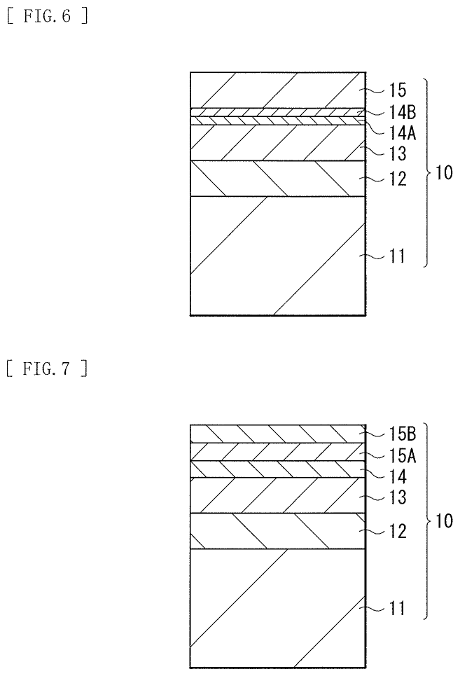

FIG. 6 illustrates an example of the configuration of the template substrate 10 that includes a plurality of second layers 14A and 14B between the first layer 13 and the third layer 15. As described above, the template substrate 10 may include the plurality of second layers 14A and 14B. For example, one of the second layers 14A and 14B includes GaN (y=0 described above), and the other includes AlGaN (0<y<1 described above). Although in FIG. 6, the second layers 14A and 14B in which two layers are stacked are illustrated, the second layer 14 may have a configuration in which three or more layers are stacked. The second layer 14 that has a superlattice structure may be provided. It is to be noted that, although in FIG. 2 described above, the relationship between the thickness t (nm) of the second layer 14 including GaN (y=0 described above) and the indium (In) composition c1 (%) of the first layer 13 is exemplified, formula (2) is adjusted on the basis of composition ratio, multilayer structure and the like of the second layer 14.

The indium (In) composition c3 (%) of the third layer 15 is preferably equal to or less than the indium (In) composition c1 (%) of the first layer 13. In other words, Alₓ₂Inₓ₁Ga₍₁₋ₓ₁₋ₓ₂₎N of the first layer 13 and Al_{z2}In_{z1}Ga_{(1-z1-z2)}N of the third layer 15 preferably satisfy formula (3) below. The indium composition of the third layer 15 is decreased as compared with the first layer 13, and thus it becomes easy to enhance the planarity of the front surface of the third layer 15.

x1≥z1 (3)

FIG. 7 illustrates an example of the configuration of the template substrate 10 that includes a plurality of third layers 15A and 15B on the second layer 14. As described above, the template substrate 10 may include the plurality of third layers 15A and 15B. The third layers 15A and 15B differ from each other in, for example, the indium (In) composition c3 (%). Although FIG. 7 exemplifies the third layers 15A and 15B in which two layers are stacked, the third layer 15 may include three or more layers that are stacked. The third layer 15 that has a superlattice structure may be provided. In the third layer 15, the indium (In) composition c3 (%) may be continuously changed in the direction of thickness. Along a direction extending from the second layer 14 toward the light emitting layer 20, the indium composition c2 (%) of the third layer 15 may be gradually increased or may be gradually decreased.

The light emitting layer 20 on the third layer 15 emits, for example, light of wavelengths in a visible region, and includes a gallium nitride (GaN)-based material. The light emitting layer 20 includes, for example, gallium indium nitride (GaInN), and emits light of red, green or blue. For example, as the wavelength of light to be generated is increased, the indium (In) composition of the light emitting layer 20 is increased. For example, the indium composition of the light emitting layer 20 that emits light of red is about 33%, the indium composition of the light emitting layer 20 that emits light of green is about 23%, and the indium composition of the light emitting layer 20 that emits light of blue is about 16%.

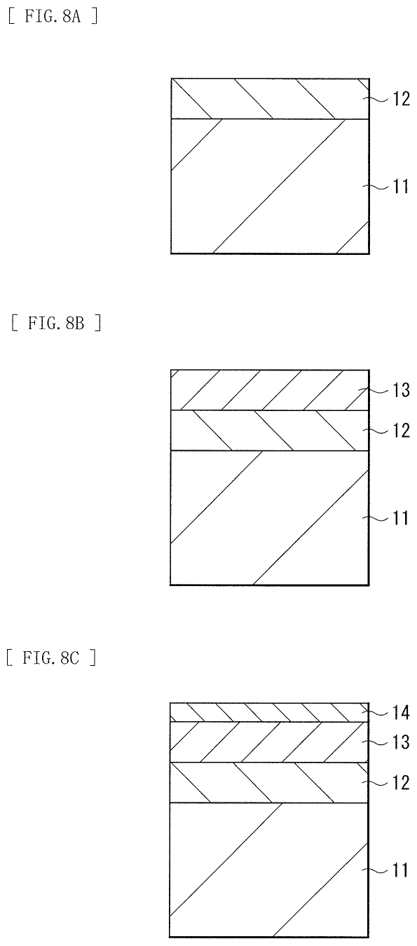

It is possible to manufacture the light emitting device 1 as described above, for example, as follows (FIGS. 8A to 8C).

As illustrated in FIG. 8A, the buffer layer 12 is first formed on the substrate 11. Specifically, at a temperature of 400° C. to 750° C., gallium indium nitride (GaInN) is grown on the substrate 11 including gallium nitride (GaN), to thereby form the buffer layer 12.

Next, as illustrated in FIG. 8B, the first layer 13 is formed on the buffer layer 12. The first layer 13 is formed by growing, for example, Alₓ₂Inₓ₁Ga₍₁₋ₓ₁₋ₓ₂₎N (0<x1<1, 0≤x2<1) at a temperature of 700° C. to 900° C. on the buffer layer 12. In the first layer 13 on the buffer layer 12 formed at a low temperature, the lattice constant a1 in the in-plane direction is greater than that in gallium nitride (GaN). In other words, the first layer 13 is formed to be lattice-relaxed.

Then, as illustrated in FIG. 8C, the second layer 14 is formed on the first layer 13 to be lattice-matched to the first layer 13. The second layer 14 is formed by coherently growing, for example, Al_{y}Ga_{(1-y)}N (0≤y<1) at a temperature of 800° C. to 1000° C. on the first layer 13. The temperature at the time when the second layer 14 is formed is preferably as high as possible in such a range as to prevent the first layer 13 from being decomposed. In this way, even when relatively large irregularities are present on the front surface of the first layer 13, the planarity of the front surface of the second layer 14 is improved, and thus the crystal defect of the first layer 13 is easily annihilated. As a carrier gas at the time when the second layer 14 is formed, hydrogen (H₂) is preferably used. Hydrogen is used to form the second layer 14, thereby promoting two-dimensional growth, thus allowing disappearance of the crystal defect described above to be facilitated.

After the formation of the second layer 14, the third layer 15 is formed on the second layer 14 to be lattice-matched to the second layer 14. The third layer 15 is formed by coherently growing, for example, Al_{z2}In_{z1}Ga_{(1-z1-z2)}N (0<z1<1, 0≤z2<1) at a temperature of 700° C. to 900° C. on the second layer 14. Thereafter, the light emitting layer 20 is formed on the third layer 15. The formation of the buffer layer 12, the first layer 13, the second layer 14, the third layer 15 and the light emitting layer 20 is performed by epitaxial crystal growth using a method such as molecular beam epitaxy (MBE: Molecular Beam Epitaxy) method or a metal organic chemical vapor deposition (MOCVD: Metal Organic Chemical Vapor Deposition) method. In this way, the light emitting device 1 illustrated in FIG. 1 is completed.

### (Workings and Effects)

In the template substrate 10 of the light emitting device 1 in the present embodiment, the third layer 15 is stacked on the lattice-relaxed first layer 13, with the second layer 14 that does not contain indium (In) being interposed therebetween. In this way, as compared with the first layer 13, the crystalline quality of the third layer 15 is improved. Hence, it is possible to enhance the light emission characteristics of the light emitting layer 20 to be disposed on the third layer 15. This is described below.

The light emission characteristics of a light emitting layer provided on a substrate or a template substrate are significantly affected by the crystalline nature, the crystal structure, and the like of the substrate or the template substrate. For a substrate or a template substrate, for example, gallium nitride is used. When a light emitting layer containing gallium indium nitride (GaInN) is provided on the substrate or the template substrate, as the indium (In) composition of the light emitting layer is increased, the lattice inconsistency degree with respect to the substrate or the template substrate is increased, thus causing the light emission characteristics to be lowered. In the substrate or the template substrate, for example, gallium nitride (GaN) is used. When it is possible to use a gallium indium nitride substrate as the substrate, it is possible to reduce the occurrence of the inconsistency described above. However, a substrate with a high crystalline nature that uses gallium indium nitride has not been currently available. Hence, it is conceivable to use template substrates (template substrates 101 and 102) according to Comparative Examples 1 and 2. In the template substrates 101 and 102, first layers (first layers 131 and 132) that are lattice-relaxed and include gallium indium nitride (GaInN) are provided.

FIG. 9 illustrates a schematic cross-sectional configuration of the template substrate 101 according to Comparative Example 1. The template substrate 101 includes a buffer layer 32 and the first layer 131 in this order on the substrate 11. In the buffer layer 32, for example, a plurality of layers including gallium indium nitride (GaInN) and a plurality of layers including gallium nitride (GaN) are alternately stacked, and as the indium (In) composition of the layers including gallium indium nitride (GaInN) is gradually increased when the layers approach the first layer 131. The buffer layer 32 as described above is provided, and thus the first layer 131 on the buffer layer 32 is lattice-relaxed with respect to gallium nitride. Hence, it is possible to decrease the lattice inconsistency degree between the first layer 131 and the light emitting layer on the first layer 131.

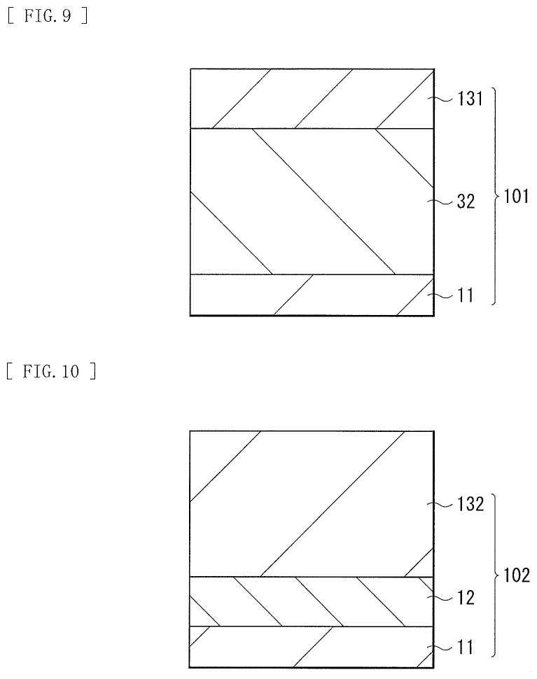

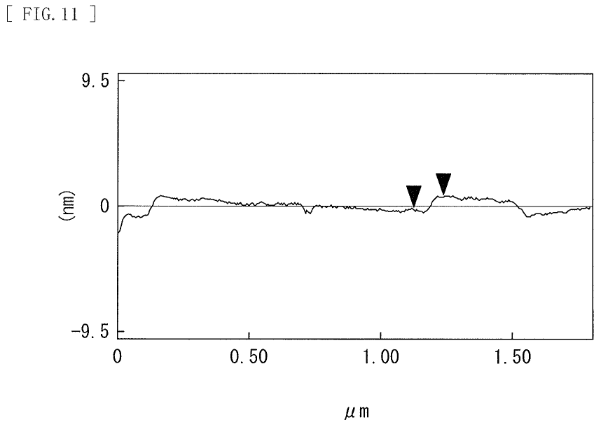

FIG. 10 illustrates a schematic cross-sectional configuration of the template substrate 102 according to Comparative Example 2. The template substrate 102 includes the buffer layer 12 and the first layer 132 in this order on the substrate 11. The first layer 132 is lattice-relaxed with respect to gallium nitride by the buffer layer 12 that is a low-temperature buffer layer. Similarly to the first layer 131 of the template substrate 101, it is possible, in the first layer 132, to decrease the lattice inconsistency degree with respect to the light emitting layer.

However, in the front surfaces of the first layers 131 and 132 that are lattice-relaxed, for example, irregularities are present whose sizes are about several nanometers to several tens of nanometers, and thus the planarity of the first layers 131 and 132 is low. Moreover, the half-value width of the peak of ω scan in the X-ray diffraction of each of the first layers 131 and 132 is, for example, equal to or greater than 500 asec, and thus the single crystalline nature of the first layers 131 and 132 is low. Furthermore, in the first layers 131 and 132, high-density crystal defects are present. In the light emitting layers that are formed on the first layers 131 and 132 whose crystalline qualities are low as described above, for example, piezo polarization is increased, and a light emission recombination probability is reduced. In other words, the light emission characteristics of the light emitting layers are lowered.

In contrast, in the template substrate 10 of the present embodiment, the third layer 15 is provided on the lattice-relaxed first layer 13, with the second layer 14 that does not contain indium (In) being interposed therebetween. The first layer 13, the second layer 14, and the third layer 15 are formed to be lattice-matched to one another. Even when, in the template substrate 10, relatively large irregularities are present in the front surface of the first layer 13, the front surface of the second layer 14 is smoothly formed, and thus the planarity of the front surface of the third layer 15 on the second layer 14 is increased.

FIG. 11 illustrates a cross-sectional profile of the front surface of the third layer 15 that is measured by an atomic force microscope (Atomic Force Microscope). As described above, it is possible to confirm that large irregularities are not present on the front surface of the third layer 15, and that steps of several monolayers are obtained.

In the template substrate 10, the annihilation of the crystal defect of the first layer 13 is facilitated when the second layer 14 is formed, and thus the third layer 15 has a low defect density and a high single crystalline nature.

As described above, in the template substrate 10, the third layer 15 is stacked on the lattice-relaxed first layer 13, with the second layer 14 that does not contain indium (In) being interposed therebetween, and thus as compared with the first layer 13, the crystalline quality of the third layer 15 is improved. Hence, the crystal of the light emitting layer 20 on the third layer 15 has a low defect density and a favorable single crystalline nature. Therefore, a non-light emission recombination probability is lowed, and a light emission recombination probability is increased. In other words, it is possible to enhance the light emission characteristics of the light emitting layer 20.

In addition, the first layer 13 is lattice-relaxed, and thus the lattice inconsistency degree between the first layer 13 (template substrate 10) and the light emitting layer 20 is decreased. Hence, the number of crystal defects generated in the light emitting layer 20 is decreased, and thus the non-light emission recombination probability is lowed. Furthermore, a piezo electric field generated in the light emitting layer 20 is decreased, and thus the light emission recombination probability is increased.

As described above, in the present embodiment, the second layer 14 that does not contain indium (In) is provided between the lattice-relaxed first layer 13 and the third layer 15. In this way, it is possible to enhance the quality of the crystal of the third layer 15. As described above, the quality of the crystal of the third layer 15 that is disposed in a position closer to the light emitting layer 20 is enhanced, and thus it is possible to enhance the light emission characteristics of the light emitting layer 20.

In other words, it is possible to enhance the light emission characteristics of the light emitting device 1, and thus the light emitting device 1 that has high external quantum efficiency and photoelectric efficiency is achieved. For example, when the light emitting device 1 is a semiconductor laser, the lattice-relaxed template substrate 10 is used, and thus it is possible to produce a laser structure that has favorable light confinement and low internal loss. In this way, it is possible to enhance the photoelectric efficiency of the semiconductor laser.

A modification example of the first embodiment described above and another embodiment are described below; however, in the following description, the same components as those in the embodiment described above are denoted with the same reference numerals, and descriptions thereof are omitted as appropriate.

### Modification Example

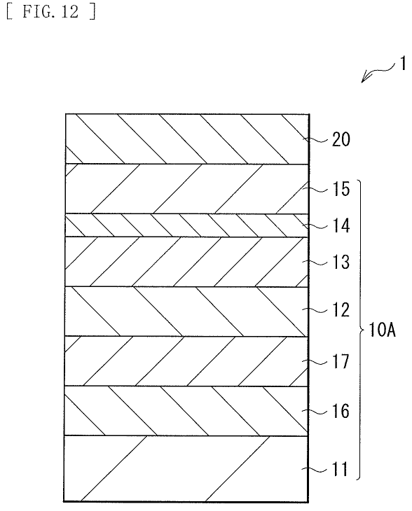

FIG. 12 illustrates a schematic cross-sectional configuration of the light emitting device 1 that includes a template substrate (a template substrate 10A) according to a modification example of the first embodiment described above. The substrate 11 of the template substrate 10A includes a heterogeneous substrate such as a sapphire substrate or a silicon (Si) substrate. Even in this case, it is also possible to obtain effects similar to those of the first embodiment described above.

For example, the buffer layer 12 is provided, for example, on the substrate 11 including a sapphire substrate, with a second buffer layer 16 and an underlayer 17 being interposed therebetween. In the sapphire substrate, for example, a c-plane is used as a main plane.

The second buffer layer 16 provided on the substrate 11 is, for example, a low-temperature buffer layer. The second buffer layer 16 includes, for example, a non-single crystal layer that includes gallium nitride (GaN), aluminum nitride (AlN) or the like.

The underlayer 17 provided on the second buffer layer 16 includes, for example, gallium nitride (GaN), gallium indium nitride (GaInN), gallium aluminum nitride (AlGaN), or aluminum gallium indium nitride (AlGaInN). On the underlayer 17, for example, the buffer layer 12, the first layer 13, the second layer 14, the third layer 15 and the light emitting layer 20 are provided in this order. As described above, the substrate 11 may include a heterogeneous substrate.

### Second Embodiment

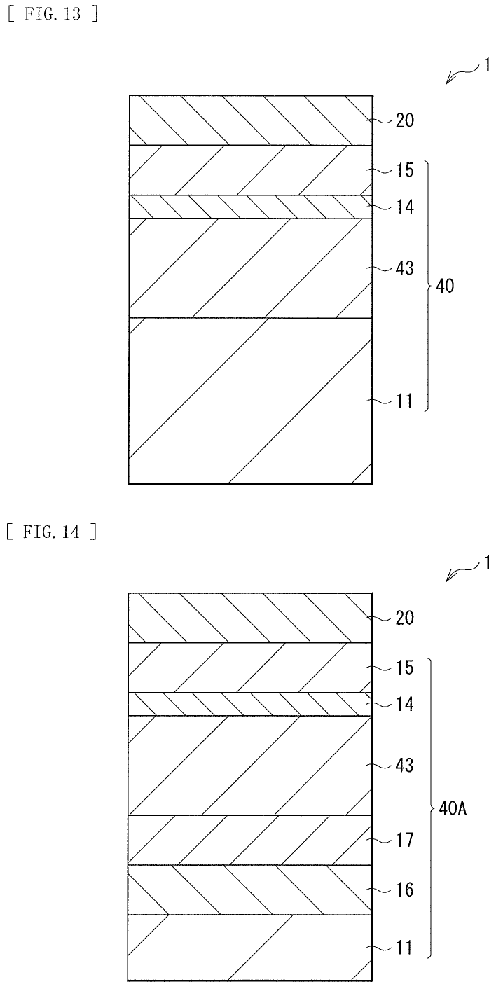

FIG. 13 schematically illustrates a cross-sectional configuration of a light emitting device 1 according to the second embodiment of the present technology. In the template substrate (template substrate 40) of the light emitting device 1, a first layer (a first layer 43) whose thickness exceeds a critical film thickness is provided on the substrate 11, and the second layer 14 and the third layer 15 are disposed in this order on the first layer 43. Except this point, the template substrate 40 has a similar configuration to that of the template substrate 10, and workings and effects thereof are also similar to those of the template substrate 10.

The first layer 43 is provided in contact with the substrate 11 that includes, for example, gallium nitride (GaN). The first layer 43 includes, as with the first layer 13 of the template substrate 10 described above, Alₓ₂Inₓ₁Ga₍₁₋ₓ₁₋ₓ₂₎N (0<x1<1, 0≤x2<1), and the indium (In) composition c1 (%) of the first layer 43 is, for example, 1% to 30%. The thickness of the first layer 43 exceeds the critical film thickness, and is, for example, 500 nm to 2000 nm. The first layer 43 that has the thickness exceeding the critical film thickness as described above has a lattice constant al greater than the lattice constant of gallium nitride (GaN) in the in-plane direction (e.g., c-plane), and is lattice-relaxed.

As with the first layer 13, the first layer 43 may include a plurality of layers (FIG. 2) or may have a superlattice structure.

FIG. 14 illustrates a schematic cross-sectional configuration of a template substrate (a template substrate 40A) that includes a substrate 11 which includes, for example, a sapphire substrate. The template substrate 40A includes, as in the modification example described above, the substrate 11, the second buffer layer 16 and the underlayer 17 in this order. The first layer 43 whose thickness exceeds the critical film thickness may be provided on the underlayer 17.

As described above, the first layer 43 may be lattice-relaxed by allowing the thickness of the first layer 43 to exceed the critical film thickness instead of the provision of the buffer layer (e.g., the buffer layer 12 of FIG. 1). Even in this case, it is also possible to obtain effects similar to those of the first embodiment described above.

Although the present technology has been described by referring to the embodiments and the modification examples, the present technology is not limited to the embodiments described above, and may be modified in a wide variety of ways. For example, the components of the light emitting device 1 illustrated in the embodiments described above, the disposition thereof, the numbers thereof and the like are merely illustrative, it is not necessary to provide all the components, and other components may be further provided. For example, another layer may be provided between each of the template substrate 10, 10A, 40, and 40A and the light emitting layer 20. Alternatively, another layer may be disposed in the upper layer of the light emitting layer 20.

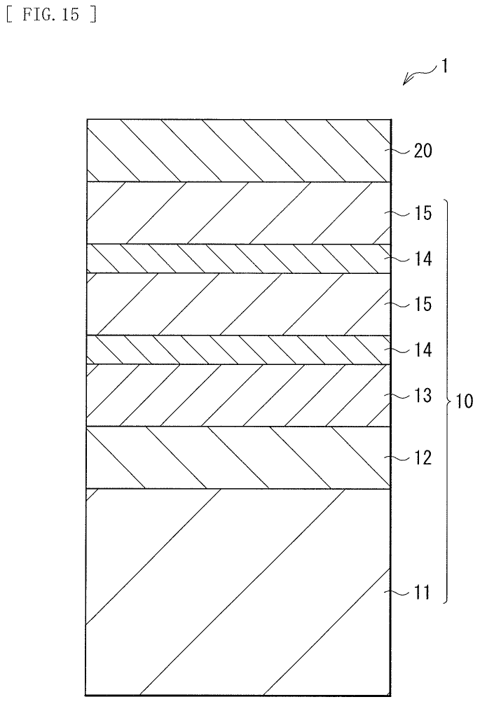

Moreover, as illustrated in FIG. 15, in the template substrate 10 (or the template substrate 10A, 40, or 40A), there may be provided, on the multilayer structure of the first layer 13 (or the first layer 43), the second layer 14 and the third layer 15, further the second layer 14 and the third layer 15, in this order.

Furthermore, description has been given, in the first embodiment and the modification example described above, of the case where the buffer layer 12 is used in order to form the lattice-relaxed first layer 13; however, the buffer layer 32 (FIG. 9) may be used, instead of the buffer layer 12, to form the lattice-relaxed first layer 13.

Furthermore, the description has been given, in the embodiments described above, etc., by referring to the example of the light emitting device 1 that includes the light emitting layer 20 on the template substrate 10, 10A, 40, or 40A, the present technology is also applicable to an electronic device that includes a functional layer other than the light emitting layer on the template substrate 10, 10A, 40, or 40A.

It is to be noted that the effects described in the present specification are merely illustrative and non-limiting, and may have other effects.

The present technology is also allowed to include configurations as described below.
(1)
   A template substrate including:
   a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed;
   a second layer that is stacked on the first layer to be lattice-matched to the first layer and includes Al_{y}Ga_{(1-y)}N (0≤y<1); and
   a third layer that is provided opposed to the first layer with the second layer being interposed therebetween, the third layer being lattice-matched to the second layer and including Al_{z2}In_{z1}Ga_{(1-z1-z2)}N (0<z1<1, 0≤z2<1).
(2)
   The template substrate according to (1), in which an inconsistency degree d (%) of a lattice constant a3 of the third layer in the in-plane direction with respect to the lattice constant a1 of the first layer that is represented by formula (1):

d(%)=|(a3−a1)|/a1×100 (1)
is less than 0.083%.
(3)
   The template substrate according to (1) or (2), in which a thickness t of the second layer satisfies formula (2):

t(nm)<1018.9×e^{-50.71×c1} (2)
where c1 in formula (2) is a content (%) of indium in the first layer, and falls within a range of 2.0%<c1<6.0%.
(4)
   The template substrate according to any one of (1) to (3), in which a front surface of the third layer has a higher degree of planarity than a front surface of the first layer.
(5)
   The template substrate according to any one of (1) to (4), in which the third layer is lower in a half-value width of a peak of ω scan in X-ray diffraction than the first layer.
(6)
   The template substrate according to any one of (1) to (5), further including a substrate,
      in which, on the substrate, the first layer, the second layer, and the third layer are provided in this order.
(7)
The template substrate according to (6), further including a buffer layer between the substrate and the first layer,
   in which the buffer layer includes gallium nitride, gallium indium nitride, gallium aluminum nitride, aluminum nitride, or aluminum gallium indium nitride.
(8)
   The template substrate according to (6) or (7), in which the substrate includes a gallium nitride substrate.
(9)
   The template substrate according to (6) or (7), in which the substrate includes a sapphire substrate or a silicon substrate.
(10)
   The template substrate according to any one of (1) to (6), in which the first layer has a thickness greater than a critical film thickness.
(11)
   The template substrate according to any one of (1) to (10), in which formula (3):

x1≥z1 (3)
is satisfied.
(12)
   An electronic device including:
   a template substrate; and
   a functional layer on the template substrate,
   the template substrate including
   a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed,
   a second layer that is stacked on the first layer to be lattice-matched to the first layer and includes Al_{y}Ga_{(1-y)}N (0≤y<1), and
   a third layer that is provided opposed to the first layer with the second layer being interposed therebetween, the third layer being lattice-matched to the second layer and including Al_{z2}In_{z1}Ga_{(1-z1-z2)}N (0<z1<1, 0≤z2<1).
(13)
   A light emitting device including:
   a template substrate; and
   a light emitting layer on the template substrate,
   the template substrate including
   a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed,
   a second layer that is stacked on the first layer to be lattice-matched to the first layer and includes Al_{y}Ga_{(1-y)}N (0≤x1<1), and
   a third layer that is provided opposed to the first layer with the second layer being interposed therebetween, the third layer being lattice-matched to the second layer and including Al_{z2}In_{z1}Ga_{(1-z1-z2)}N (0<z1<1, 0≤z2<1).
(14)
   A method of manufacturing a template substrate, the method including:
   forming a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed;
   forming, on the first layer, a second layer in which Al_{y}Ga_{(1-y)}N (0≤y<1) is coherently grown; and
   forming, on the second layer, a third layer in which Al_{z2}In_{z1}Ga_{(1-z1-z2)}N (0<z1<1, 0≤z2<1) is coherently grown.
(15)
   The method of manufacturing the template substrate according to (14), in which the forming of the second layer involves crystal growth using hydrogen as a carrier gas.
(16)
   The method of manufacturing the template substrate according to (14) or (15), in which the forming of the second layer is performed at a temperature higher than a temperature at which the forming of the first layer is performed
(17)
   A method of manufacturing an electronic device, the method including forming, after formation of a template substrate, a functional layer on the template substrate,
   the formation of the template substrate including
   forming a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed,
   forming, on the first layer, a second layer in which Al_{y}Ga_{(1-y)}N (0≤y<1) is coherently grown, and
   forming, on the second layer, a third layer in which Al_{z2}In_{z1}Ga_{(1-z1-z2)}N (0<z1<1, 0≤z2<1) is coherently grown.

This application claims the benefit of Japanese Priority Patent Application JP2017-156416 filed with the Japan Patent Office on Aug. 14, 2017, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A template substrate comprising:
a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed;
a second layer that is stacked on the first layer to be lattice-matched to the first layer and includes Al_{y}Ga_{(1-y)}N (0≤y<1); and
a third layer that is provided opposed to the first layer with the second layer being interposed therebetween, the third layer being lattice-matched to the second layer and including Al_{z2}In_{z1}Ga_{(1-z1-z2)}N (0<z1<1, 0≤z2<1).

2. The template substrate according to claim 1, wherein an inconsistency degree d (%) of a lattice constant a3 of the third layer in the in-plane direction with respect to the lattice constant a1 of the first layer that is represented by formula (1):
d(%)=|(a3−a1)|/a1×100 (1)
is less than 0.083%.

3. The template substrate according to claim 1, wherein a thickness t of the second layer satisfies formula (2):
t(nm)<1018.9×e^{-50.71×c1} (2)
where c1 in formula (2) is a content (%) of indium in the first layer, and falls within a range of 2.0%<c1<6.0%.

4. The template substrate according to claim 1, wherein a front surface of the third layer has a higher degree of planarity than a front surface of the first layer.

5. The template substrate according to claim 1, wherein the third layer is lower in a half-value width of a peak of ω scan in X-ray diffraction than the first layer.

6. The template substrate according to claim 1, further comprising a substrate, wherein, on the substrate, the first layer, the second layer, and the third layer are provided in this order.

7. The template substrate according to claim 6, further comprising a buffer layer between the substrate and the first layer,
wherein the buffer layer includes gallium nitride, gallium indium nitride, gallium aluminum nitride, aluminum nitride, or aluminum gallium indium nitride.

8. The template substrate according to claim 6, wherein the substrate includes a gallium nitride substrate.

9. The template substrate according to claim 6, wherein the substrate includes a sapphire substrate or a silicon substrate.

10. The template substrate according to claim 1, wherein the first layer has a thickness greater than a critical film thickness.

11. The template substrate according to claim 1, wherein formula (3):
x1≥z1 (3)
is satisfied.

12. An electronic device comprising:
a template substrate; and
a functional layer on the template substrate,
the template substrate including
a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed,
a second layer that is stacked on the first layer to be lattice-matched to the first layer and includes Al_{y}Ga_{(1-y)}N (0≤y<1), and
a third layer that is provided opposed to the first layer with the second layer being interposed therebetween, the third layer being lattice-matched to the second layer and including Al_{z2}In_{z1}Ga^{(1-z1-z2)}N (0<z1<1, 0≤z2<1).

13. A light emitting device comprising:
a template substrate; and
a light emitting layer on the template substrate,
the template substrate including
a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed,
a second layer that is stacked on the first layer to be lattice-matched to the first layer and includes Al_{y}Ga_{(1-y)}N (0≤y<1), and
a third layer that is provided opposed to the first layer with the second layer being interposed therebetween, the third layer being lattice-matched to the second layer and including Al_{z2}In_{z1}Ga_{(1-z1-z2)}N (0≤z1<1, 0≤z2<1).

14. A method of manufacturing a template substrate, the method comprising:
forming a first layer that includes Alₓ₂Inₓ₁Ga₍₁₋ₓ₁₋ₓ₂₎N (0<x1<1, 0≤x2<1) and has a lattice constant a1 in an in-plane direction greater than a lattice constant of GaN in the in-plane direction, the first layer being lattice-relaxed;
forming, on the first layer, a second layer in which Al_{y}Ga_{(1-y)}N (0≤y<1) is coherently grown; and
forming, on the second layer, a third layer in which Al_{z2}In_{z1}Ga_{(1-z1-z2)}N (0<z1<1, 0≤z2<1) is coherently grown.

15. The method of manufacturing the template substrate according to claim 14, wherein the forming of the second layer involves crystal growth using hydrogen as a carrier gas.

16. The method of manufacturing the template substrate according to claim 14, wherein the forming of the second layer is performed at a temperature higher than a temperature at which the forming of the first layer is performed

17. A method of manufacturing an electronic device, the method comprising forming, after formation of a template substrate, a functional layer on the template substrate,
the formation of the template substrate including
forming a first layer that includes Alₓ₂Inₓ₁Ga₍₁₋ₓ₁₋ₓ₂₎N (0≤x1<1, 0≤x2<1) and has a lattice constant a1 in an in-plane direction greater than a lattice constant of GaN in the in-plane direction, the first layer being lattice-relaxed,
forming, on the first layer, a second layer in which Al_{y}Ga_{(1-y)}N (0≤y<1) is coherently grown, and
forming, on the second layer, a third layer in which Al_{z2}In_{z1}Ga_{(1-z1-z2)}N (0<z1<1, 0≤z2<1) is coherently grown.
